(19) United States
(12) Patent Application Publication
(10) Pub. No.: US 2015/0162354 A1
(43) Pub. Date: Jun. 11, 2015

(54) THIN FILM TRANSISTOR SUBSTRATE AND METHOD OF MANUFACTURING A THIN FILM TRANSISTOR SUBSTRATE

(71) Applicant: Samsung Display Co., LTD., Yongin-City (KR)

(72) Inventors: Kang-Moon JO, Seoul (KR); Joon-Geol KIM, Hwaseong-si (KR); Seung-Ho JUNG, Yongin-si (KR); Young-Joo CHOI, Anyang-si (KR)

(73) Assignee: Samsung Display Co., LTD., Yongin-City (KR)

(21) Appl. No.: 14/249,176

(22) Filed: Apr. 9, 2014

(30) Foreign Application Priority Data
Dec. 9, 2013 (KR) 10-2013-0152015

(51) Int. Cl. H01L 27/12; H01L 21/02; H01L 27/15

(52) U.S. Cl. CPC H01L 27/1214; H01L 27/1259; H01L 27/153; H01L 21/02483

(57) ABSTRACT

Rather than forming a data line continuously extending in one layer of a thin film transistor substrate, spaced apart segments of a first data connection pattern are formed in a same first layer as that of the gate lines but extending in a crossing direction. Spaced apart parts of a second data connection pattern are formed in a same second layer as that of the source electrodes of the substrate and also extending in the crossing direction. The segments of the first data connection pattern are connected to successive parts of the second data connection pattern to form completed data lines. In one embodiment, the gate lines of the first layer and the spaced apart segments of a first data connection pattern include a low resistivity metal such as copper.

### PRIORITY STATEMENT

This application claims priority under 35 U.S.C. §119 to Korean Patent Application No. 10-2013-0152015, filed on Dec. 9, 2013, and all the benefits accruing therefrom, the contents of which are herein incorporated by reference in its entirety.

### BACKGROUND

1. Field of Disclosure

The present disclosure of invention relates to a thin film transistor substrate of a display device. More particularly, exemplary embodiments relate to patterning and disposition of various wirings in a thin film transistor substrate that may be used for a display device, and a method of manufacturing the thin film transistor substrate.

2. Description of Related Technology

Generally, a thin film transistor (TFT) configured for driving a pixel unit in a display device includes a gate electrode, a source electrode, a spaced apart drain electrode, and an active pattern, the latter defining a channel between the source electrode and the drain electrode. The active pattern includes a semiconductive layer which may include amorphous silicon, polycrystalline silicon, a semiconductive oxide, or the like.

Amorphous silicon has a relatively low electron mobility, which may be about 1 to about 10 cm²/V, so that a thin film transistor including amorphous silicon has relatively low driving characteristics. In contrast, polycrystalline silicon has a relatively high electron mobility, which may be about 10 to about hundreds cm²/V. However, a crystallization process is required for forming polycrystalline silicon. Thus, it is difficult to form a uniform polycrystalline silicon layer on a large-sized substrate, and resulting manufacturing costs are high. By contrast, semiconductive oxides may be formed through a low-temperature process, and may be easily used in large-scaled substrates, and such have a high electron mobility. Thus, research is actively being conducted on thin film transistors which include an semiconductive oxide and in methods for optimizing performance and manufacturability.

It is to be understood that this background of the technology section is intended to provide useful background for understanding the here disclosed technology and as such, the technology background section may include ideas, concepts or recognitions that were not part of what was known or appreciated by those skilled in the pertinent art prior to corresponding invention dates of subject matter disclosed herein.

### SUMMARY

The present disclosure of invention provides a thin film transistor substrate having an improved reliability and electrical characteristics.

Exemplary embodiments also provided of methods of manufacturing the thin film transistor substrate.

According to an exemplary embodiment, a thin film transistor substrate includes a gate line extending in a first direction within a first layer on a base substrate, a gate electrode electrically connected to the gate line, a first data connection pattern formed of segments extending in a second direction different from the first direction and disposed in the same first layer as that of the gate line, an active pattern overlapping with the gate electrode, a source electrode formed in a second layer above the first layer and electrically connected to the active pattern, a drain electrode spaced apart from the source electrode and a second data connection pattern disposed in a same second layer as that of the source electrode and electrically connected to the source electrode and to the segments of the first data connection pattern so as to form a continuous data line.

In an embodiment, the thin film transistor substrate further includes a gate pad and a signal line. The gate pad is disposed in a same layer as the gate line and connected to the gate line. The signal line is disposed in a same layer as the second data connection pattern and contacting the gate pad to provide a gate signal.

In an embodiment, the thin film transistor substrate further includes a gate insulation layer and an etch-stop layer. The gate insulation layer covers the gate line, the gate electrode and the first data connection pattern. The etch-stop layer covers the gate insulation layer and the active pattern.

In an embodiment, the second data connection pattern is disposed on the etch-stop layer, and contacts the first data connection pattern through the gate insulation layer and the etch-stop layer.

In an embodiment, the thin film transistor substrate further includes a gate insulation layer and an etch-stop pattern. The gate insulation layer covers the gate line, the gate electrode and the first data connection pattern. The etch-stop pattern is disposed on the active pattern.

In an embodiment, the second data connection pattern is disposed on the gate insulation layer, and contacts the first data connection pattern through the gate insulation layer.

In an embodiment, the second data connection pattern is connected to the segments of the first data connection pattern.

In an embodiment, the second data connection pattern includes a transparent conductive oxide.

In an embodiment, the second data connection pattern has a single-layered structure or a multiple-layered structure including titanium.

In an embodiment, the active pattern includes a semiconductive oxide.

According to an exemplary embodiment, a method for manufacturing a thin film transistor substrate is provided. In the method, a gate metal pattern is formed on a base substrate. The gate metal pattern includes a gate line extending in a first direction, a gate electrode electrically connected to the gate line and spaced apart segments of a first data connection pattern extending in a second direction different from the first direction. An active pattern overlapping with the gate electrode is formed. A source metal pattern is formed. The source metal pattern includes a source electrode electrically connected to the active pattern, a drain electrode spaced apart from the source electrode, and a second data connection pattern electrically connected to the source electrode and to the segments of the first data connection pattern.

In an embodiment, the gate metal pattern further includes a gate pad connected to the gate line, and the source metal pattern further includes a signal line contacting the gate pad to provide a gate signal.

In an embodiment, a gate insulation layer is formed to cover the gate line, the gate electrode and the first data connection pattern. An etch-stop layer is formed to cover the gate insulation layer and the active pattern.

In an embodiment, a first photoresist pattern is formed on the etch-stop layer. The first photoresist pattern has through holes overlapping with the gate pad and the first data connection pattern. The first photoresist pattern includes a first thickness portion and a second thickness portion thicker than the first thickness portion. The etch-stop layer and the gate insulation layer are etched by using the first photoresist pattern as a mask to expose the gate pad and the first data connection pattern. The first photoresist pattern is partially removed to form a second photoresist pattern having through holes overlapping with the active pattern. The etch-stop layer is etched by using the second photoresist pattern as a mask to expose a portion of the active pattern.

In an embodiment, a gate insulation layer is formed to cover the gate line, the gate electrode and the first data connection pattern. An active layer is formed on the gate insulation layer. An etch-stop layer is formed on the active layer. A first photoresist pattern is formed on the etch-stop layer. The first photoresist pattern has through holes overlapping with the gate pad and the first data connection pattern. The first photoresist pattern includes a first thickness portion and a second thickness portion thinner than the first thickness portion. The etch-stop layer, the active layer and the gate insulation layer are etched by using the first photoresist pattern as a mask to expose the gate pad and the first data connection pattern. The first photoresist pattern is partially removed to form a second photoresist pattern overlapping with the active pattern. The etch-stop layer and the active layer are etched by using the second photoresist pattern as a mask to form an active pattern. The second photoresist pattern is partially removed to form a third photoresist pattern. The remaining etch-stop layer is etched by using the third photoresist pattern as a mask to form an etch-stop pattern.

According to the exemplary embodiments, a first portion of a data line is formed by the segments of the first data connection pattern which are formed within the same layer as that of the gate lines. Thus, a gate pad may be directly connected to a gate lines driver circuit.

Furthermore, a semiconductive oxide layer does not remain under a data line. Thus, problems due to an active protrusion may be prevented.

Furthermore, an active pattern is exposed after a gate pad is exposed in the process of etching an etch-stop layer to expose the active pattern and the gate pad. Thus, damage to the active pattern may be prevented. Furthermore, the above processes may be performed without an additional mask by using half-tone light exposure.

### BRIEF DESCRIPTION OF THE DRAWINGS

The above and other features and advantages will become more apparent by describing exemplary embodiments thereof with reference to the accompanying drawings, in which:

FIGS. 1 and 2 are plan views illustrating a thin film transistor substrate according to an exemplary embodiment.

FIG. 3 is a cross-sectional view taken along the line I-I′ of FIG. 2.

FIGS. 4 to 13 are cross-sectional views illustrating a method for manufacturing the thin film transistor substrate illustrated in FIGS. 1 to 3.

FIG. 14 is a plan view illustrating a thin film transistor substrate according to another exemplary embodiment.

FIG. 15 is a cross-sectional view taken along the line II-IF of FIG. 14.

FIGS. 16 to 24 are cross-sectional views illustrating a method for manufacturing the thin film transistor substrate illustrated in FIGS. 14 and 15.

### DETAILED DESCRIPTION

Exemplary embodiments will be described more fully hereinafter with reference to the accompanying drawings, in which various embodiments are shown.

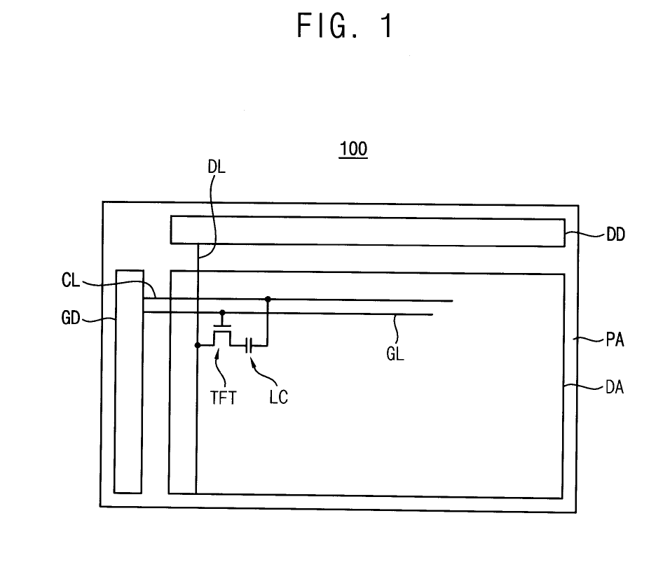

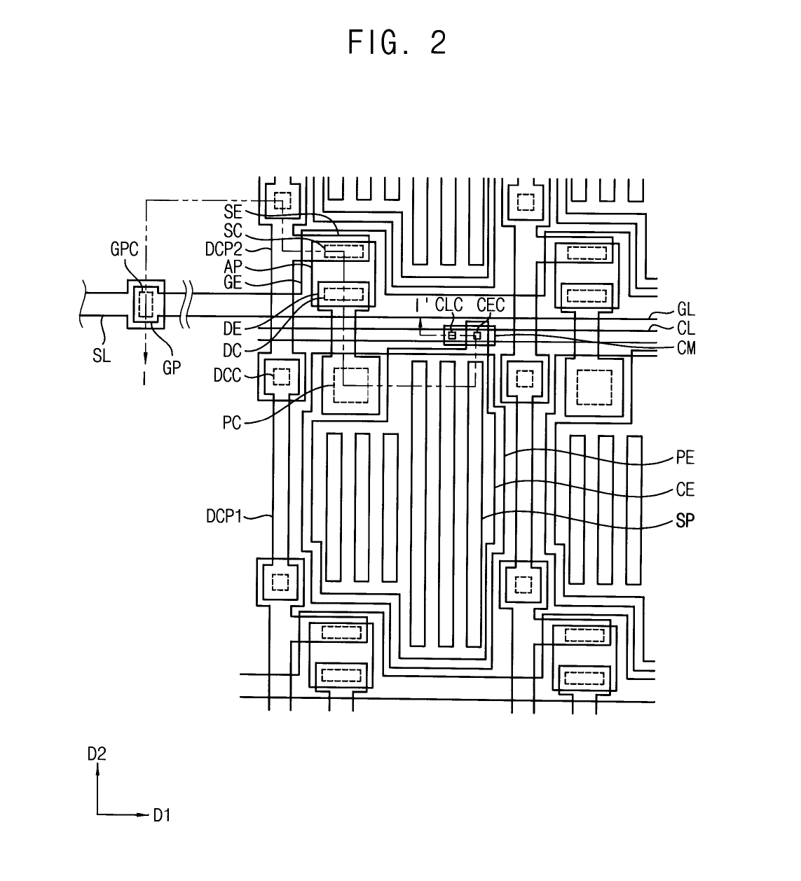

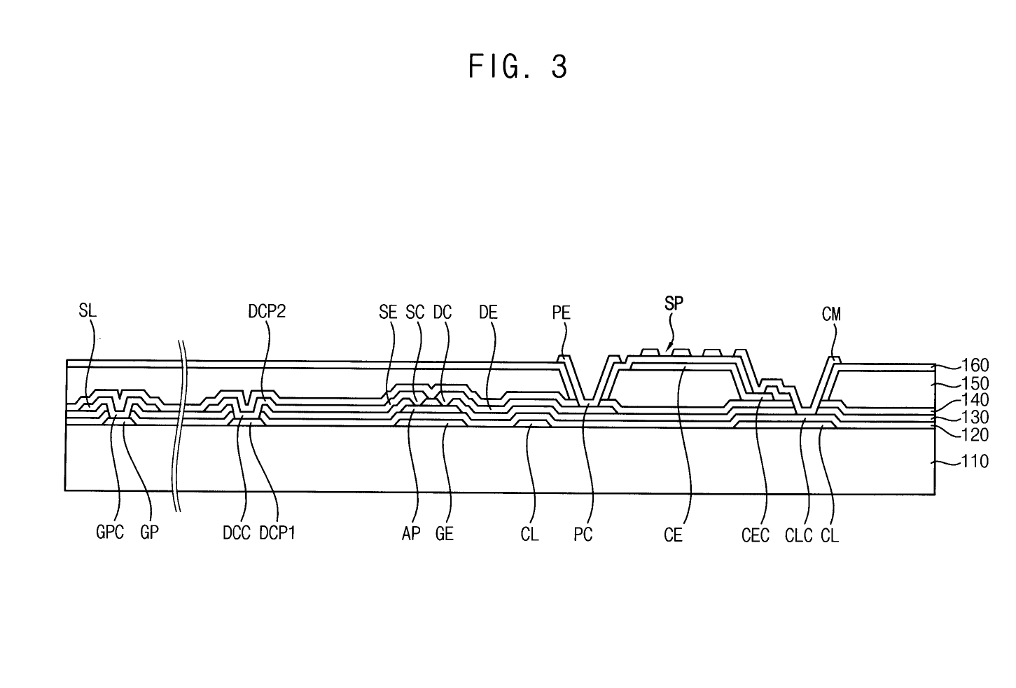

FIGS. 1 and 2 are top plan views illustrating a thin film transistor substrate according to an exemplary embodiment. FIG. 3 is a cross-sectional view taken along the line I-I′ of FIG. 2.

Referring to FIGS. 1 to 3, a thin film transistor (TFT) substrate may be used as part of a liquid crystal display panel for a liquid crystal display device. For example, the liquid crystal display panel may include the TFT substrate, an opposing substrate facing the display substrate and a liquid crystal layer interposed between the TFT substrate and the opposing substrate.

The thin film transistor substrate may include a display area DA configured for displaying images and a non-displaying peripheral area PA surrounding the display area DA. An array of pixel-driving thin film transistors (TFTs) is disposed in the display area DA.

Each pixel-driving thin film transistor TFT is electrically connected to a corresponding gate line GL and a corresponding data line DL of the respective pixel. A drain electrode of the thin film transistor TFT is electrically connected to a respective pixel electrode PE. The pixel electrode PE forms a transparent plate portion of a liquid crystal capacitor LC while a common electrode CE forms the opposed plate and is electrically connected to a common line CL.

A gate lines driver circuit GD providing gate signals to the gate lines GL and a data lines driver circuit DD providing data signals to the data lines DL may be disposed in the peripheral area PA. The gate lines driver GD and the data lines driver DD may be connected to an external control unit to receive driving and control signals therefrom.

In one embodiment, the gate lines driver GD may include thin film transistors monolithically integrated on a base substrate. Thus, the gate lines driver circuit GD may be formed through a same process as that used for the pixel-driving thin film transistors TFT of the display area DA. The data lines driver DD may also be monolithically integrated on the base substrate, or may be mounted as separate chip on a tape carrier package, a flexible printed circuit board or the like.

The pixel-driving thin film transistors (TFTs) each include a gate electrode GE, an active pattern AP, a source electrode SE and a spaced apart drain electrode DE.

The gate lines GL extend longitudinally in a first direction D1, and the data lines DL extend longitudinally in a different second direction D2, when viewed in a plan view sense. The first direction D1 intersects with the second direction D2. Furthermore, the first direction D1 may be substantially perpendicular to the second direction D2.

The data lines of the here-disclosed embodiments each include a plurality of interconnection-providing portions respectively disposed in different layers. More particularly, each data line includes a first data connection pattern DCP1 disposed in a same layer as that of the gate lines GL, and a second data connection pattern DCP2 disposed in a same layer as that of the source electrodes SE. The first data connection pattern DCP1 is spaced apart from the gate lines GL with which it shares a same disposition layer. Yet more specifically, the first data connection pattern DCP1 is segmented such as to be disposed between successive gate lines. On the other hand, the second data connection pattern DCP2 which does not shares a same disposition layer with the gate lines includes segments which extend above and thus overlap the underlying gate lines GL.

In one embodiment, respective segments of the first data connection pattern DCP1 and of the second data connection pattern DCP2 are alternately disposed along the second direction D2 and joined together to form a correspondingly extending data line (DL). More specifically, each segment of the first data connection pattern DCP1 is electrically connected to two successive but spaced apart segments of the second data connection patterns DCP2. Similarly, each segment of the second data connection pattern DCP2 is electrically connected to two successive but spaced apart segments of the first data connection pattern DCP1. As a result, co-extensive and interconnected segments of the first data connection pattern DCP1 and of the second data connection pattern DCP2 form a longitudinally extending data line DL that may be used for transmitting a respective data signal across the display area DA in the second direction D2.

More specifically, in one embodiment each first end of a respective first data connection pattern segment DCP1 overlaps with a respective first end of a to-be-connected-to second data connection pattern segment DCP2. Similarly, each opposed second end of the first data connection pattern segment DCP1 overlaps with a respective second end of a to-be-connected-to end of another (next successive) second data connection pattern segment. In order to improve contact reliability between the interconnected ends of the first data connection pattern segments DCP1 and of the second data connection pattern segments DCP2, the to-be-interconnected respective ends of the first data connection pattern DCP1 and of the second data connection pattern DCP2 may be formed to have enlarged sizes as compared to the intermediate portions of the first and second data connection pattern segments that are respectively interposed between the enlarged ends.

The gate line GL is electrically connected to the gate electrodes GE of its respective pixels. For example, the gate electrode GE may protrude (integrally branch out) from the gate line GL in the second direction D2. In another embodiment, a portion of the gate line GL may overlap with the active pattern AP to function as the gate electrode GE so that there is no need for a branched out gate electrode GE protruding from the gate line GL.

An end of the gate line GL is connected to a respective gate pad GP. The gate pad GP is disposed in the peripheral area PA outside of, and surrounding, the display area DA. A gate signal is applied to the gate line GL through the gate pad GP. The gate pad GP contacts a signal line SL transmitting the gate signal. The signal line SL may be electrically connected to a drain electrode of a thin film transistor of the gate lines driver circuit GD.

The thin film transistor substrate further includes a common line CL electrically connected to the common electrode CE to provide a common voltage to the common electrode CE. The common line CL may be disposed in a same layer as that of the gate line GL.

The thin film transistor substrate further includes a gate insulation layer 120 that covers the gate electrodes GE, the gate lines GL, the common line CL and the first data connection pattern segments DCP1.

The active pattern AP overlaps with the gate electrode GE. The active pattern AP is disposed on top of the gate insulation layer 120. The active pattern AP includes a semiconductive oxide. When a gate voltage is applied to the gate electrode GE, a channel portion of the active pattern AP becomes conductive to thereby provide electrical interconnection between the source and drain electrodes of the respective TFT.

The thin film transistor substrate further includes an etch-stop layer 130 covering the active pattern AP.

The source electrode SE and the drain electrode DE are spaced apart from each other, and contact the active pattern AP, respectively. The source electrode SE and the drain electrode DE extend on top of the etch-stop layer 130.

The etch-stop layer 130 has a plurality of contact holes. A source contact SC of the source electrode SE and a drain contact DC of the drain electrode DE respectively allow for source and drain contact with the active pattern AP through the respective contact holes of the etch-stop layer 130.

The second data connection pattern DCP2 is seamlessly connected to the source electrode SE. For example, the source electrode SE protrudes as an integral branch from the second data connection pattern DCP2 in the first direction D1.

The signal line SL may be disposed in a same layer as that of the source electrode SE. The signal line SL contacts the gate pad GP through a respective contact hole formed through the gate insulation layer 120 in the peripheral area PA.

In an embodiment, the respective signal line SL of the gate lines driver circuit GD is directly connected to the corresponding gate pad GP unlike a conventional thin film transistor substrate that uses a transparent conductive pattern as an interconnected bridge. Thus, a space for the bridge is not necessary. Thus, a bezel of a display panel including the thin film transistor substrate may be reduced in size. Furthermore, connection failure dues to damage to the bridge or inflow of static electricity through the bridge may be prevented.

The thin film transistor substrate further includes a passivation layer 140 covering the thin film transistor, and an organic insulation layer 150 covering the passivation layer 140 and planarizing the substrate. The segment of the common electrode CE opposed to the respective pixel electrode PE is disposed on the organic insulation layer 150. The thin film transistor substrate further includes a pixel insulation layer 160 covering the common electrode CE. The pixel electrode PE is disposed on the pixel insulation layer 160.

In the embodiment, the pixel electrode PE is disposed on top of the common electrode CE as strips (slitted portions). However, the pixel electrode PE may be disposed under the common electrode CE in another embodiment. Furthermore, the common electrode CE may be formed on an opposing substrate spaced apart from the thin film transistor substrate in yet another embodiment.

The pixel electrode PE is disposed on the pixel insulation layer 160. The pixel electrode PE has a slit portion SP. The slit portion SP may extend, for example, in the second direction D2, and may includes a plurality of slits arranged in the first direction D1. The pixel electrode PE overlaps with the common electrode CE to form an electric field that extends into the liquid crystal layer where strength of the electric field depends on a voltage applied between the pixel and common electrodes so as to thereby control an optical orientation of liquid crystal molecules disposed thereon. The pixel electrode PE includes a pixel contact PC passing through the pixel insulation layer 160, the organic insulation layer 150 and the passivation layer 140 to contact the drain electrode DE.

The common electrode CE and the pixel electrode PE may each include a transparent conductive material such as indium zinc oxide (IZO), indium tin oxide (ITO) or the like.

The thin film transistor substrate further includes a connection member CM electrically connecting the common electrode CE to the common line CL. The connection member CM may be disposed in a same layer as that of the pixel electrode PE. The connection member CM includes a common electrode contact CEC and a common line contact CLC. The common electrode contact CEC passes through the pixel insulation layer 160 to contact the common electrode CE, and the common line contact CLC passes through the pixel insulation layer 160, the organic insulation layer 150, the passivation layer 140, the etch-stop layer 130 and the gate insulation layer 120 to contact the common line CL.

In another embodiment, the thin film transistor substrate may further include a color filter and/or a black matrix disposed on the passivation layer 140.

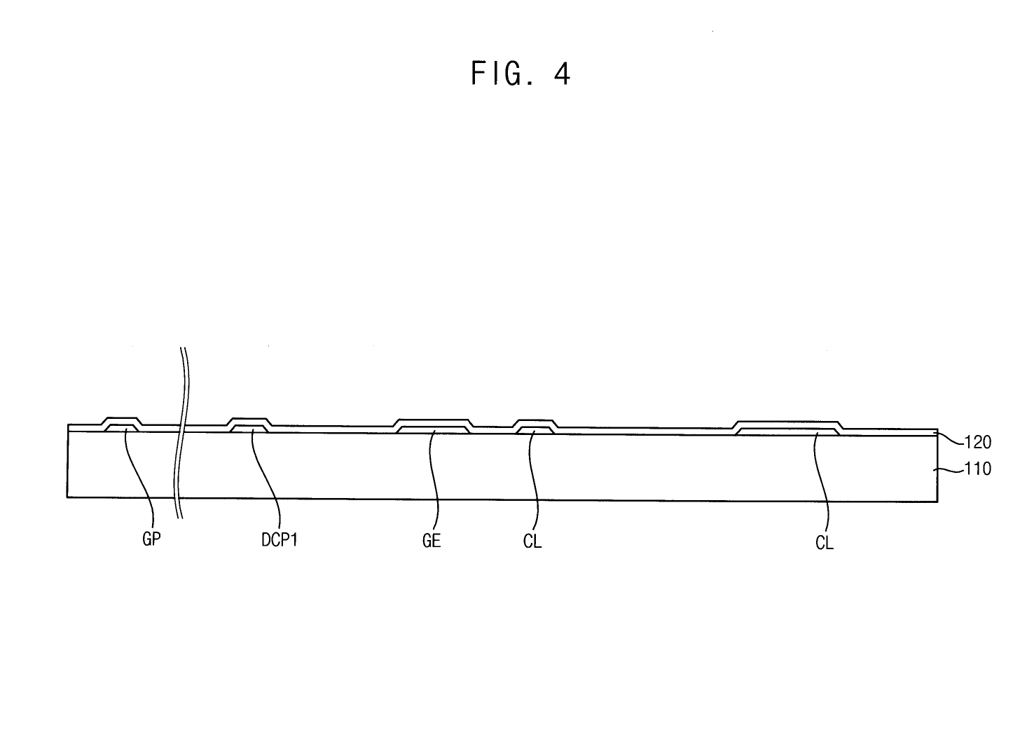

FIGS. 4 to 13 are cross-sectional views illustrating a method for manufacturing the thin film transistor substrate illustrated in FIGS. 1 to 3.

Referring to FIG. 4, a gate metal layer is formed on a base substrate 110, and patterned to form a gate metal pattern including gate electrodes GE, the segments of the first data connection pattern DCP1, a common line CL and the gate pads GP. The gate metal pattern further includes a gate line GL continuously connected to the respective gate electrodes GE and to the respective gate pad GP. The segments of the first data connection pattern DCP1 may be disposed between successive ones of the gate lines and may extend in a direction perpendicular to the gate lines.

Examples of the base substrate 110 may include a glass substrate, a quartz substrate, a silicon substrate, a plastic substrate and the like.

Examples of a material that may be used for the gate metal layer may include copper, silver, chromium, molybdenum, aluminum, titanium, manganese, or an alloy thereof. The gate metal layer may have a single-layered structure or may have a multiple-layered structure including different conductive materials. For example, the gate metal layer may include a copper layer and one or more titanium layers disposed on and/or under the copper layer.

In another embodiment, the gate metal layer may include one or more metal layers and one or more conductive oxide layers disposed on and/or under the metal layer(s). For example, the gate metal layer(s) may include a copper layer and the conductive oxide layer(s) disposed on and/or under the copper layer may be optically transparent and/or chemically resistant to one or more predefined etchants Examples of a material that may be used for the conductive oxide layer may include indium zinc oxide (IZO), indium tin oxide (ITO), gallium zinc oxide (GZO), and zinc aluminum oxide (ZAO).

Since the layer of the gate lines GL and gate electrodes GE further includes the first data connection pattern segments DCP1 made of substantially the same materials and framing the sides of the respective pixel electrode aperture areas, the blocking and/or back reflecting of leakage light from the backlighting subsystem behaves substantially the same for the sides of the respective pixel electrode aperture areas where the first data connection pattern segments DCP1 are present as they do for the tops and/or bottoms of the respective pixel electrode aperture areas where the corresponding gate lines (GL) are present and thus the processing of backlighting light that is incident on sides and tops and/or bottoms of the respective pixel electrode aperture areas are substantially the same as opposed to being different. Moreover, when the gate lines GL are made as high quality conductors, the portion of the data lines that are formed by the first data connection pattern segments DCP1 enjoy the advantages of the same high quality conductor structures. Yet further, because the first data connection pattern segments DCP1 are disposed on areas of the base substrate 110 that might otherwise go unused and because the corresponding areas of the source electrode (SE) layer are freed up for optional other uses, efficiency in utilization of subareas of the various layers is increased. And in addition to this, because there is less etching away of the gate line layer conductor materials that are initially blanket deposited on the base substrate 110, there is less wastage of materials and manufacturing efficiencies are thus improved.

Still referring to FIG. 4, after the materials of the gate lines layer are blanket deposited and appropriately patterned, a gate insulation layer 120 is formed to cover the gate layer metal pattern. Examples of a material that may be used for the gate insulation layer 120 may include a silicon nitride (SiNx), a silicon oxide (SiOx), a silicon oxynitride (SiOxNy), an aluminum oxide, a hafnium oxide, a titanium oxide and the like. The gate insulation layer 120 may have a single-layered structure or a multiple-layers structure. For example, the gate insulation layer 120 may include a lower insulation layer predominantly including a silicon nitride and a further insulation layer on top of it and predominantly including a silicon oxide. In a triple layer structure it may define an ONO sequence.

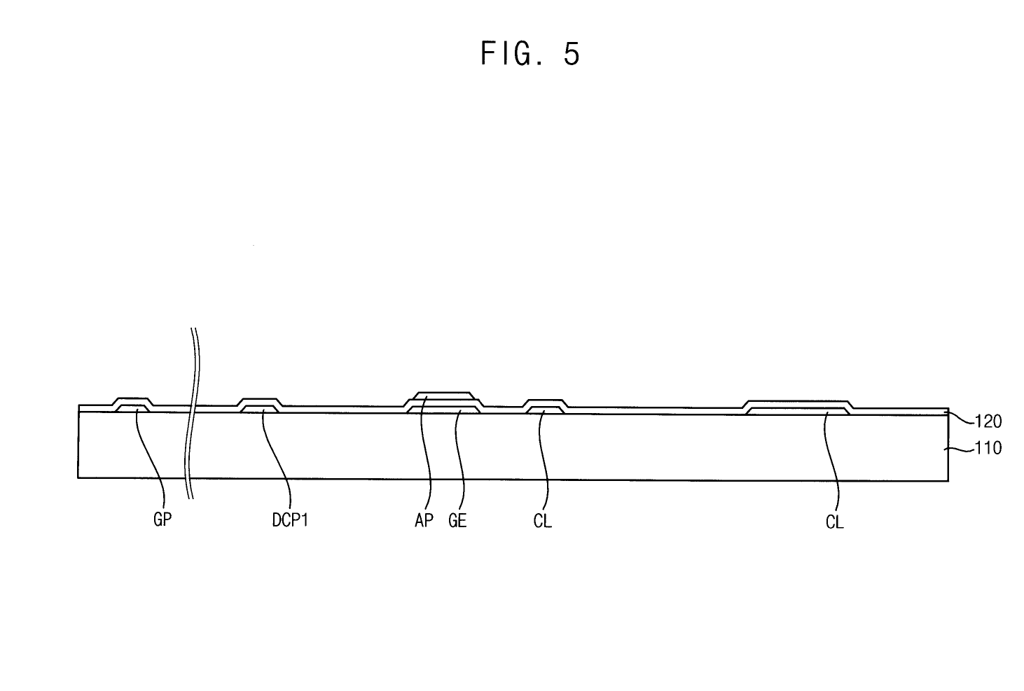

Referring to FIG. 5, an active layer is formed on the gate insulation layer 120 and patterned to form an active pattern AP. The active pattern AP includes a semiconductive oxide. Examples of the semiconductive oxide may include zinc oxide, zinc tin oxide, indium zinc oxide, indium oxide, titanium oxide, indium gallium zinc oxide, indium zinc tin oxide and the like. The active pattern AP overlaps with the gate electrode GE.

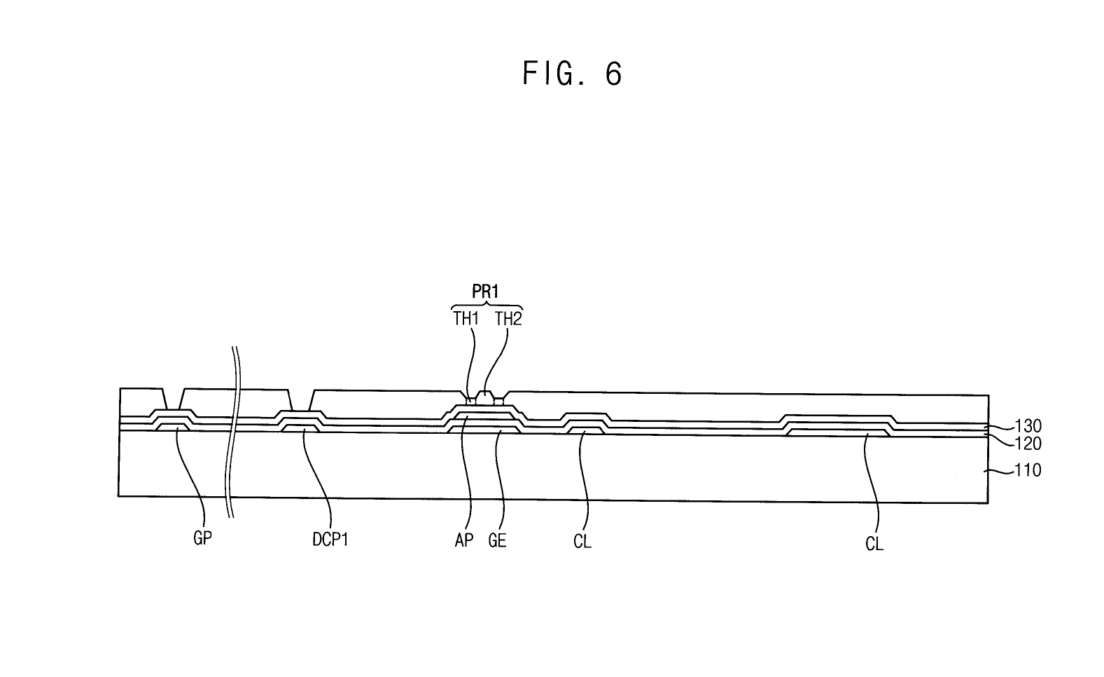

Referring to FIG. 6, an etch-stop layer 130 is formed to protectively cover the active pattern AP. Examples of a material that may be used for the etch-stop layer 130 may include a silicon nitride, a silicon oxide, an aluminum oxide, a hafnium oxide, a titanium oxide and the like.

A first photoresist pattern PR1 is formed on the etch-stop layer 130. The first photoresist pattern PR1 may be formed on substantially an entire portion of the etch-stop layer 130.

The first photoresist pattern PR1 is patterned to have through holes exposing a portion of the etch-stop layer 130. For example, a first through hole may overlap with a to-be-contacted portion of the gate pad GP, and a second through hole may overlap with a to-be-contacted portion of the first data connection pattern DCP1.

The first photoresist pattern PR1 includes a first thickness portion TH1 and a second thickness portion TH2 thicker than the first thickness portion TH1. The first thickness portion TH1 overlaps with the source and drain regions of the active pattern AP.

For example and to form the first and second thickness portions TH1 and TH2, a photoresist composition is coated, and exposed to a light through a half-tone exposure and developed by a developing solution to form the first photoresist pattern PR1.

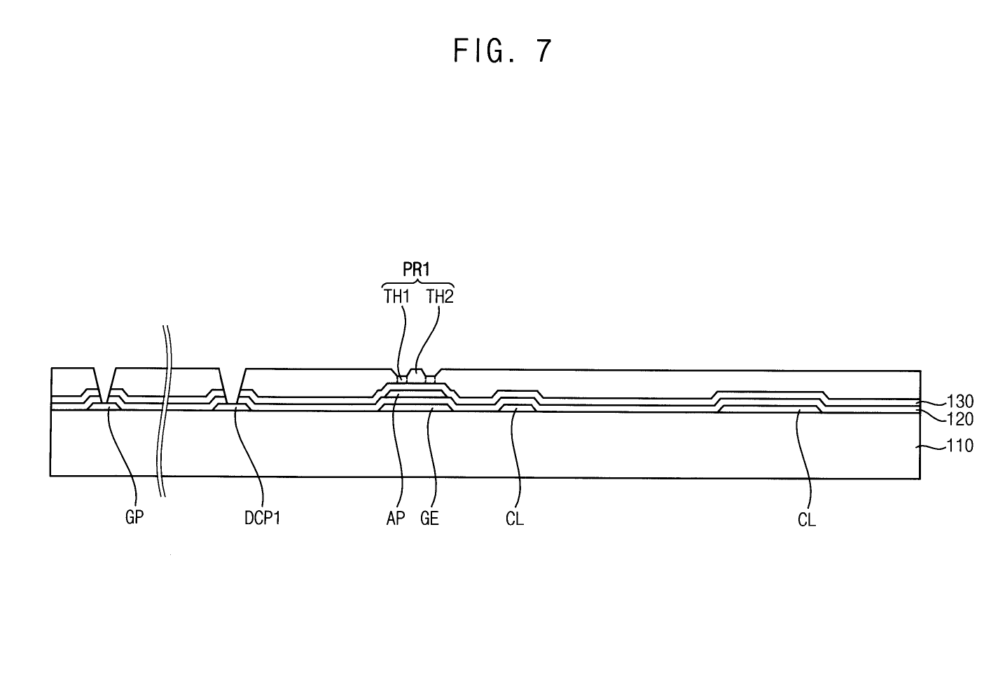

Referring to FIG. 7, the etch-stop layer 130 and the gate insulation layer 120 are etched through where exposed by using the first photoresist pattern mask PR1 as a mask. Thus, the to-be-contacted portions of the gate pad GP and of the first data connection pattern DCP1 are exposed.

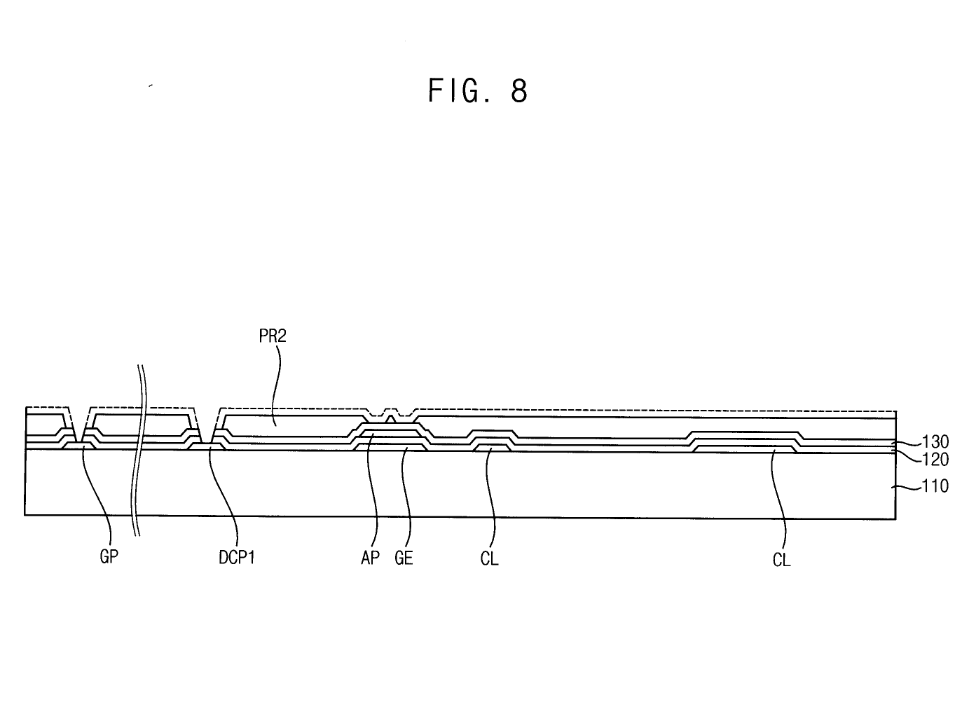

Referring to FIG. 8, the first photoresist pattern PR1 is partially removed, for example, through a depth limited ashing process. As a result, the first thickness portion TH1 is removed but the second thickness portion TH2 partially remains to form a second photoresist pattern PR2, in particular one that provides a spaced apart for the to-be-formed source and drain electrodes.

The second photoresist pattern PR2 has a through hole exposing the etch-stop layer 130 overlapping with the active pattern AP. Furthermore, through the ashing process, an upper surface of the etch-stop layer 130 adjacent to the gate pad GP and the first data connection pattern DCP1 may be exposed.

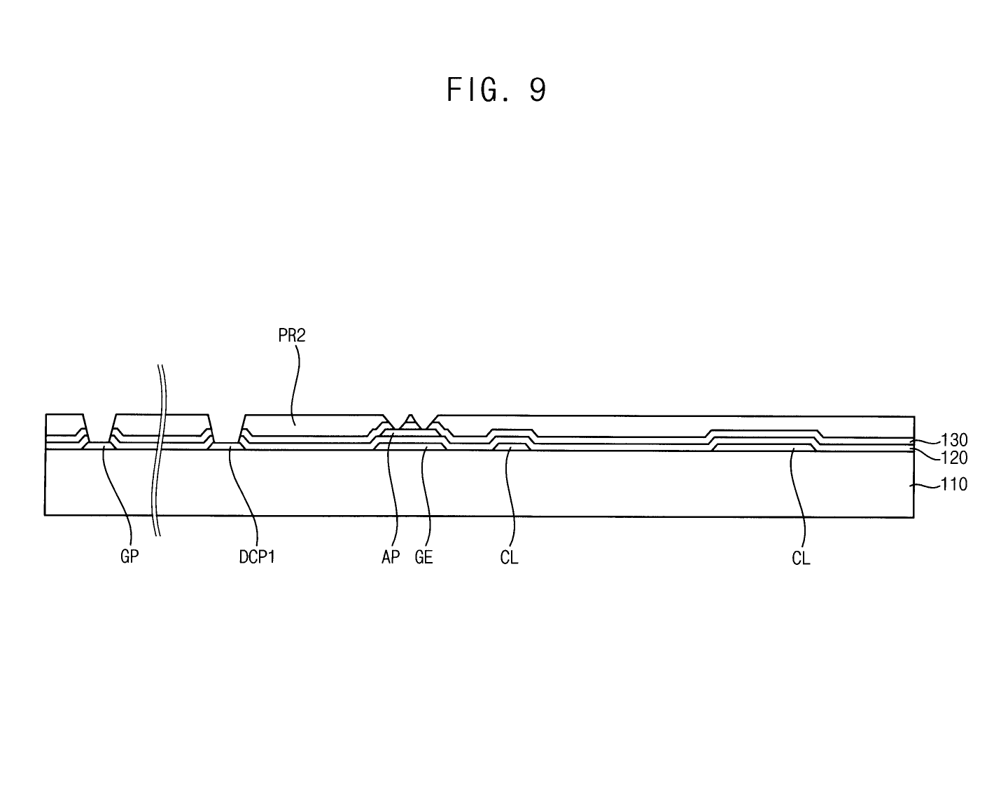

Referring to FIG. 9, the etch-stop layer 130 is etched by using the second photoresist pattern PR2 as a mask to form through holes exposing portions of the active pattern AP where the spaced apart and to-be-formed source and drain electrodes are to be formed.

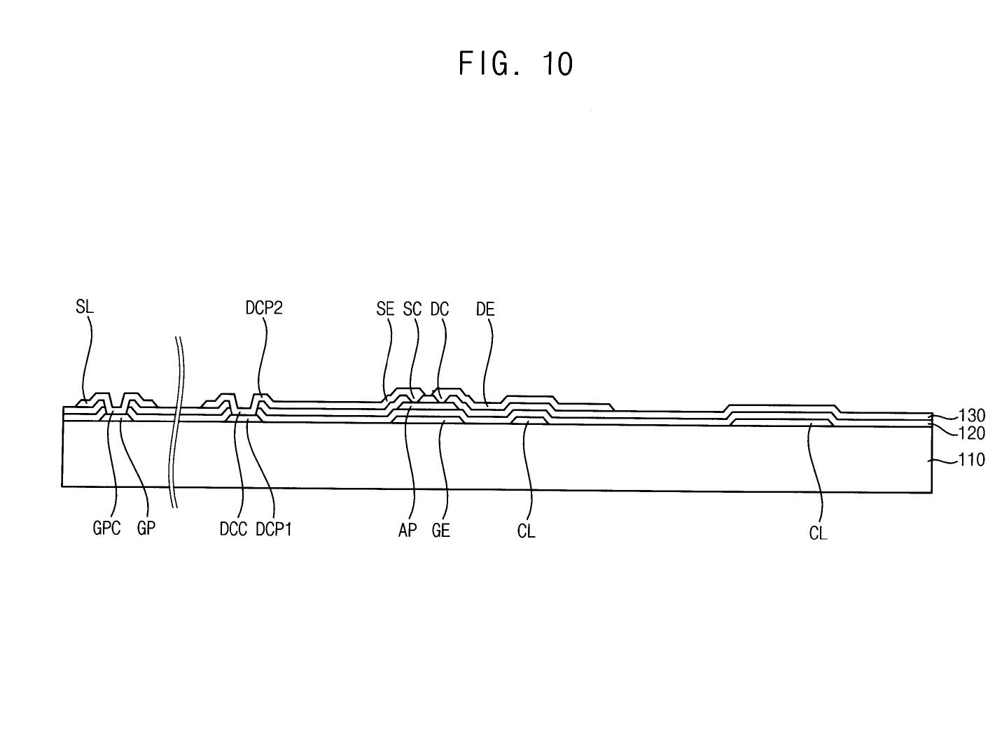

Referring to FIG. 10, a source metal layer is formed on the patterned etch-stop layer 130 after the second photoresist pattern PR2 is selectively removed.

In an embodiment, the source metal layer may include titanium. Particularly, the source metal layer may have a titanium single-layered structure or a multiple-layered structure further including one or more different and additional metal layers. For example, the source metal layer may have a double-layered structure of a lower titanium layer and an upper copper layer, or a triple-layered structure of titanium/aluminum/titanium or titanium/copper/titanium.

In another embodiment, the source metal layer may have a single-layered structure of a transparent conductive oxide. According to a conventional method, a data line does not include a transparent conductive oxide as a main layer because of low conductivity. In the embodiment, a source electrode, a drain electrode and a portion of a data line may be formed from a transparent conductive oxide. The source metal layer including a transparent conductive oxide may be etched by a same etchant as used for the pixel electrodes.

Thus, etchants required for manufacturing a thin film transistor substrate may be reduced if the source metal layer includes a transparent conductive oxide.

The source metal layer is patterned to form a source metal pattern including a second data connection pattern DCP2, a source electrode SE, a drain electrode DE and a signal line SL. The second data connection pattern DCP2 is continuously connected to the source electrode SE. In one embodiment, the conduction distance from the data contact DCC to the source electrode SE is substantially smaller than the conduction length of a corresponding and immediately adjacent first data connection pattern segment DCP1 so that overall resistance of the composite data line (DL) is predominantly determined by the resistance of the first data connection pattern segments DCP1 rather than that of the second data connection pattern segments DCP2.

The source electrode SE includes a source contact SC passing through the etch-stop layer 130 to contact the active pattern AP. The drain electrode DE includes a drain contact DC passing through the etch-stop layer 130 to contact the drain electrode portion of the active pattern AP.

The second data connection pattern DCP2 includes a data contact DCC passing through the gate insulation layer 120 and the etch-stop layer 130 to contact the corresponding segment of the first data connection pattern DCP1.

As illustrated in FIG. 1 the thin film transistor substrate according to an exemplary embodiment includes a thin film transistor constituting the gate lines driver GD, and the thin film transistor may be formed through a same process as the thin film transistor in the display area DA. Thus, the signal line SL may be a portion of a drain electrode of the thin film transistor in the gate lines driver GD, or may be connected to the drain electrode of thin film transistor in the gate lines driver circuit GD.

In one embodiment, the signal line SL includes a gate pad contact GPC passing through the gate insulation layer 120 and the etch-stop layer 130 to contact the gate pad GP. Thus, a width of a bezel of a display panel may be reduced. Furthermore, reliability deterioration due to using a bridge may be prevented.

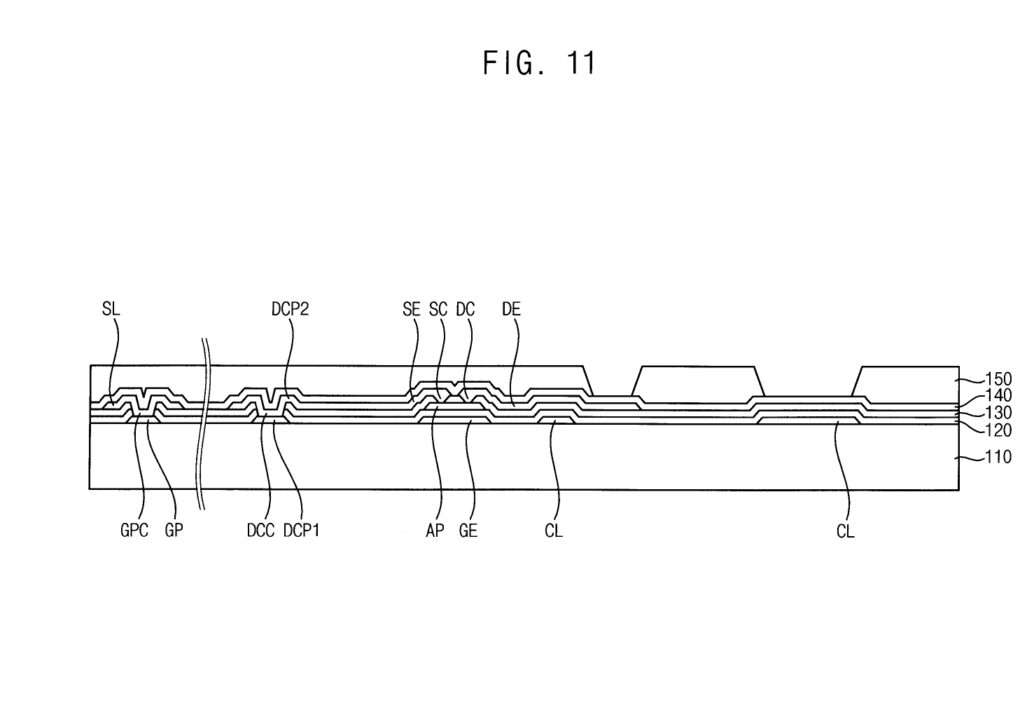

Referring to FIG. 11, a passivation layer 140 is formed to cover the source metal pattern, and an organic insulation layer 150 is formed on the passivation layer 140. The passivation layer 140 may include an inorganic insulation material such as a silicon oxide, a silicon nitride or the like. The organic insulation layer 150 planarizes an upper surface of the substrate. The organic insulation layer 150 is patterned to form through holes. The through holes may overlap with the drain electrode DE and the common line CL.

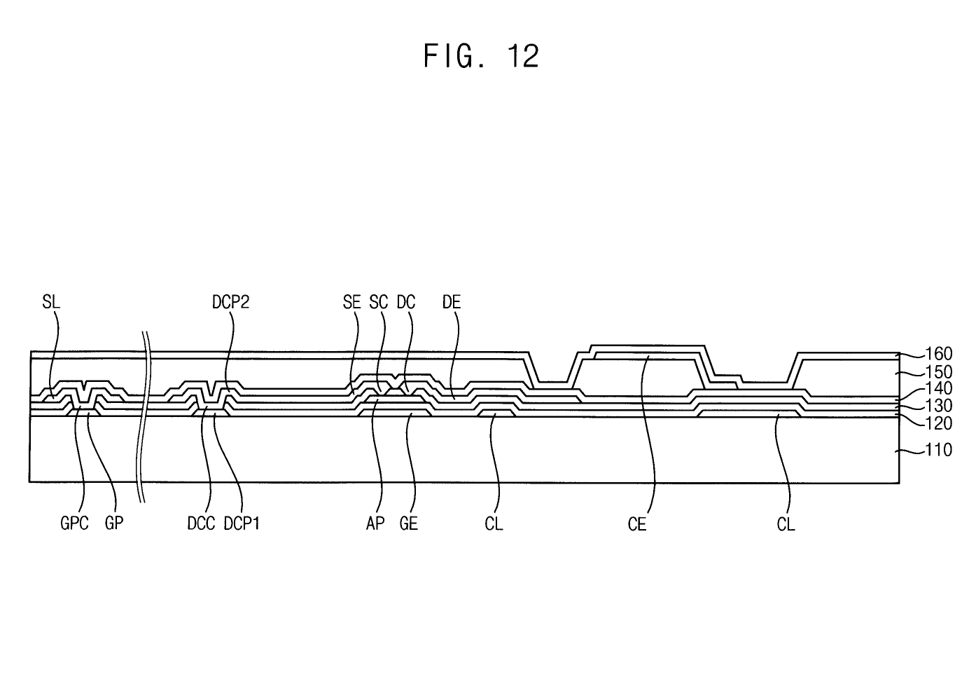

Referring to FIG. 12, a first transparent conductive layer is formed on the organic insulation layer 150, and then patterned to form a common electrode CE.

A pixel insulation layer 160 is formed to cover the formed common electrode CE and the organic insulation layer 150. The pixel insulation layer 160 may include an inorganic insulation material such as a silicon oxide, a silicon nitride or the like.

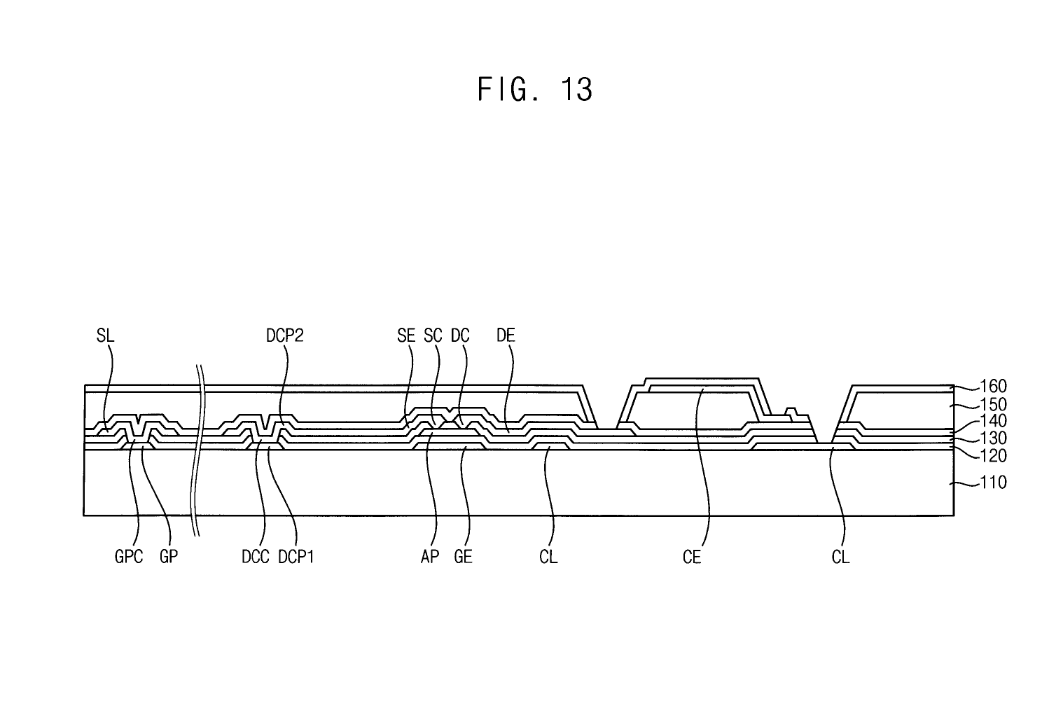

Referring to FIG. 13, the pixel insulation layer 160, the passivation layer 140, the eth-stop layer 130 and the gate insulation layer 120 are patterned to form through holes. For example, the through holes include a first through hole exposing the drain electrode DE, a second through hole exposing the common electrode CE and a third through hole exposing the common line CL.

A second transparent conductive layer is then formed on the pixel insulation layer 160, and patterned to form a pixel electrode PE and a connection member CM. The pixel electrode PE contacts the drain electrode DE and overlaps with the common electrode CE. The pixel electrode PE has an opening forming a slits portion SP extending in a direction. The connection member CM contacts the common electrode CE and the common line CL so that the common electrode CE and the common line CL are electrically connected to each other.

According to one embodiment and as described above, a portion of each data line is formed as segments within a same layer as that of the gate lines and using substantially the same materials. Thus, a gate pad may be directly connected to a monolithically integrated gate lines driver (GD).

Furthermore, a semiconductive oxide layer does not need to remain continuously under a data line that is continuously in a higher layer. Thus, problems associated with an active layer protrusion may be prevented.

Furthermore, an active pattern is exposed after a gate pad is exposed in the process of etching an etch-stop layer to expose the active pattern and the gate pad. Thus, damage to the active pattern due to the prior etching step may be prevented. Furthermore, the above processes may be performed without an additional mask by using half-tone light exposure.

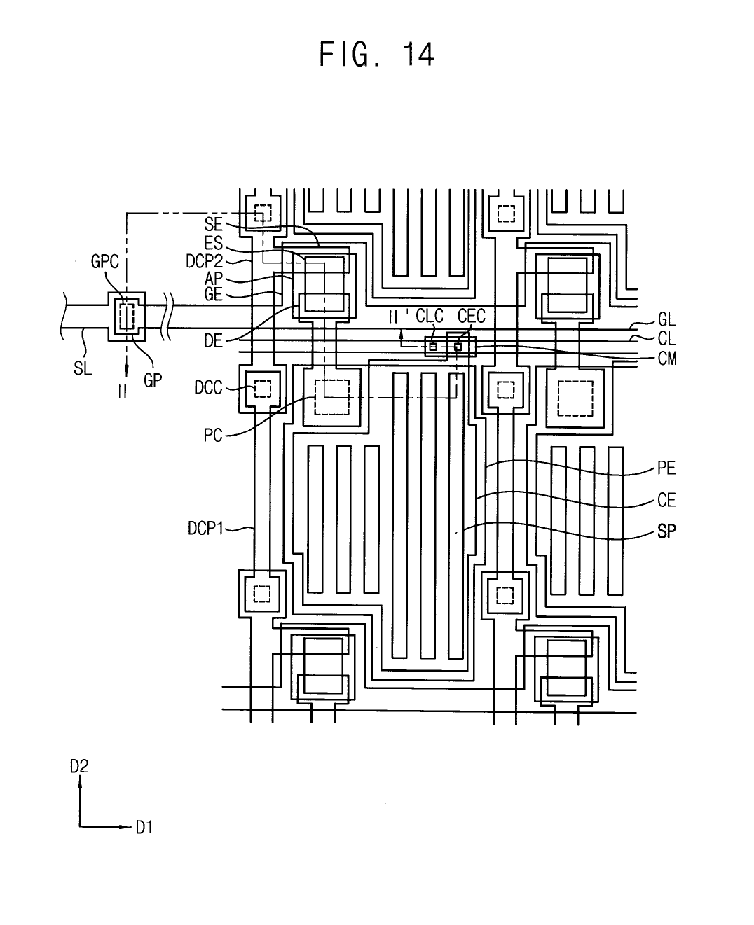

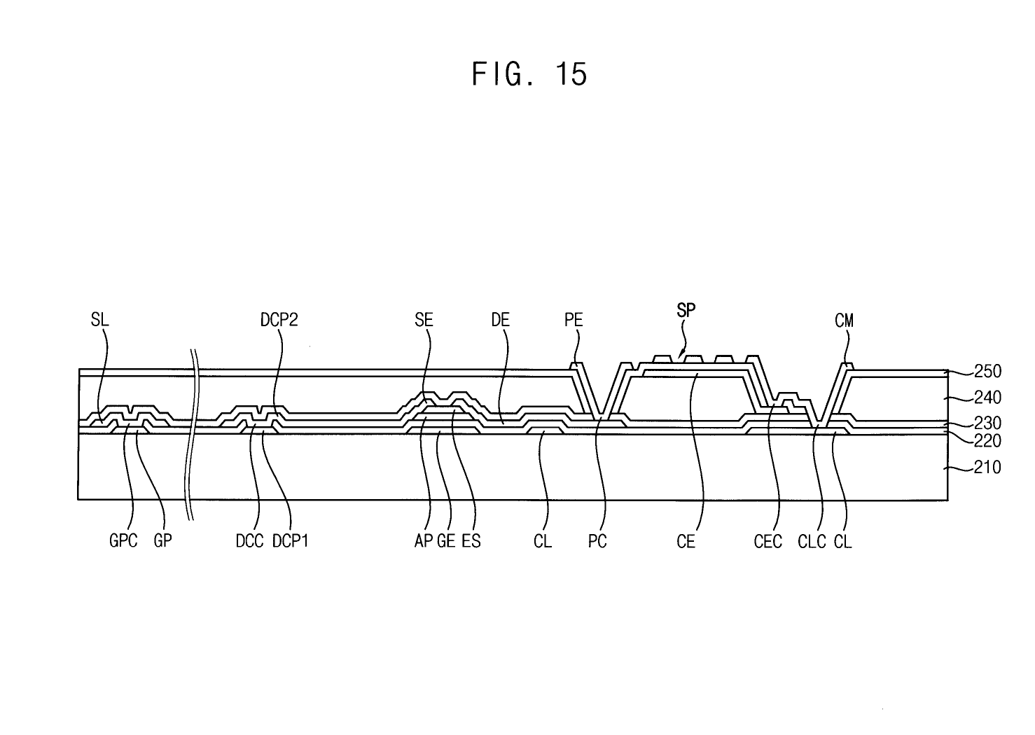

FIG. 14 is a plan view illustrating a thin film transistor substrate according to another exemplary embodiment. FIG. 15 is a cross-sectional view taken along the line II-IF of FIG. 14.

A thin film transistor substrate illustrated in FIGS. 14 and 15 may be substantially the same as the thin film transistor substrate illustrated in FIGS. 2 and 3 except for including an etch-stop pattern having an island shape instead of the etch-stop layer of the previous embodiment. Thus, any duplicated explanation will be omitted.

The thin film transistor substrate includes an etch-stop pattern ES disposed on an active pattern AP. Examples of a material that may be used for the etch-stop pattern ES may include a silicon nitride, a silicon oxide, an aluminum oxide, a hafnium oxide, a titanium oxide and the like.

The etch-stop pattern ES may have a smaller size than the active pattern AP in a plan view. For example, the active pattern AP is overlapped by substantially an entire lower surface of the etch-stop pattern ES.

A source electrode SE and a drain electrode DE contact the exposed sidewall surfaces of the active pattern AP. The source electrode SE and the drain electrode DE may extend to cover a portion of an upper surface of the etch-stop pattern ES.

A signal line SL is electrically connected to a gate line GL. The signal line SL includes a gate pad contact GPC passing through a gate insulation layer 220 to contact a gate pad GP.

A first data connection pattern DCP1 is disposed in a same layer as that of the gate line GL. A second data connection pattern DCP2 is disposed in a same layer as that of the source electrode SE. The second data connection pattern DCP2 includes a data contact DCC passing through the gate insulation layer 220 to contact the first data connection pattern DCP1.

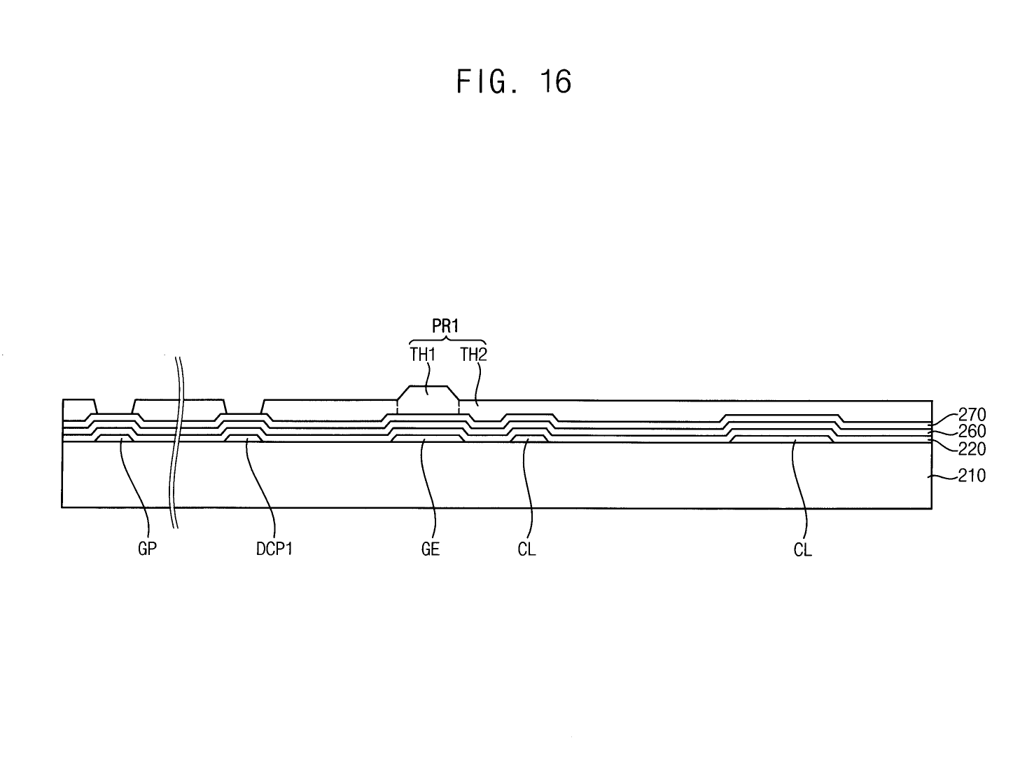

FIGS. 16 to 24 are cross-sectional views illustrating a method for manufacturing the thin film transistor substrate illustrated in FIGS. 14 and 15.

Referring to FIG. 16, a gate metal layer is formed on a base substrate 210, and patterned to form a gate metal pattern including a, gate line, a gate electrode GE, a first data connection pattern DCP1, a common line CL and a gate pad GP.

A gate insulation layer 220 is formed to cover the gate metal pattern. An active layer 260 and an etch-stop layer 270 are formed on the gate insulation layer 220. A first photoresist pattern PR1 is formed on the etch-stop layer 270. The first photoresist pattern PR1 may be formed on substantially an entire portion of the etch-stop layer 270.

The first photoresist pattern PR1 has through holes exposing a portion of the etch-stop layer 130. For example, a first through hole may overlap with the gate pad GP, and a second through hole may overlap with the first data connection pattern DCP1.

The first photoresist pattern PR1 includes a first thickness portion TH1 and a second thickness portion TH2, the latter being thinner than the first thickness portion TH1. The first thickness portion TH1 overlaps with the gate electrode GE.

For example, a photoresist composition is coated, and exposed to a light through a half-tone exposure and developed by a developing solution to form the illustrated first photoresist pattern PR1.

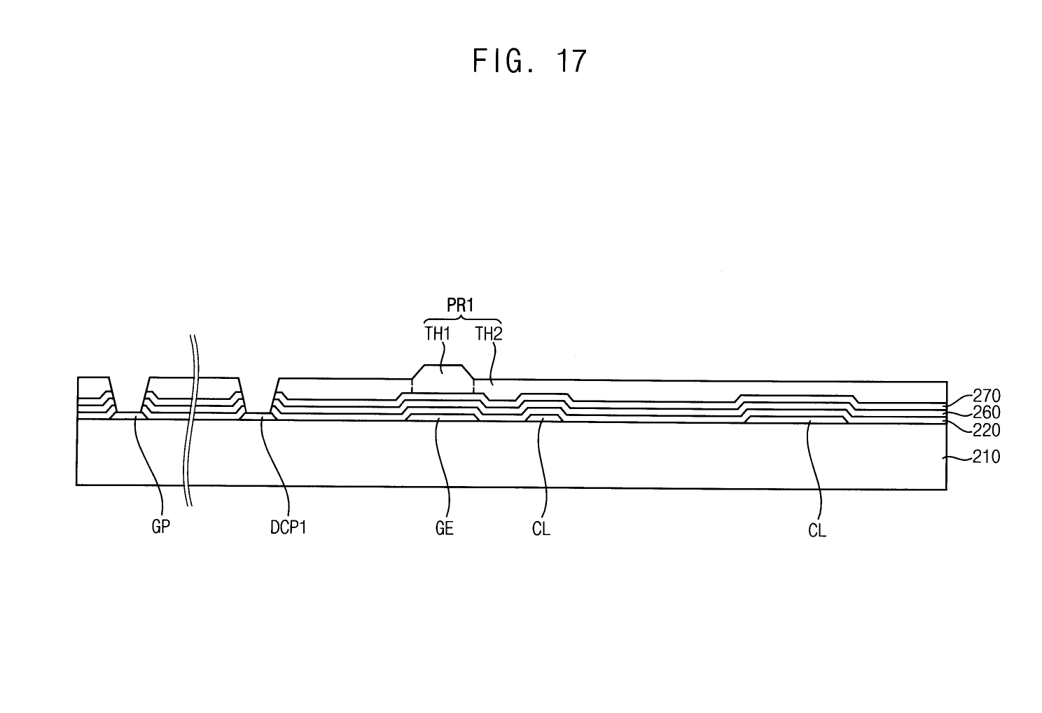

Referring to FIG. 17, the etch-stop layer 270, the active layer 260 and the gate insulation layer 220 are etched by using the first photoresist pattern mask PR1 as a mask. Thus, the gate pad GP and the first data connection pattern DCP1 are exposed.

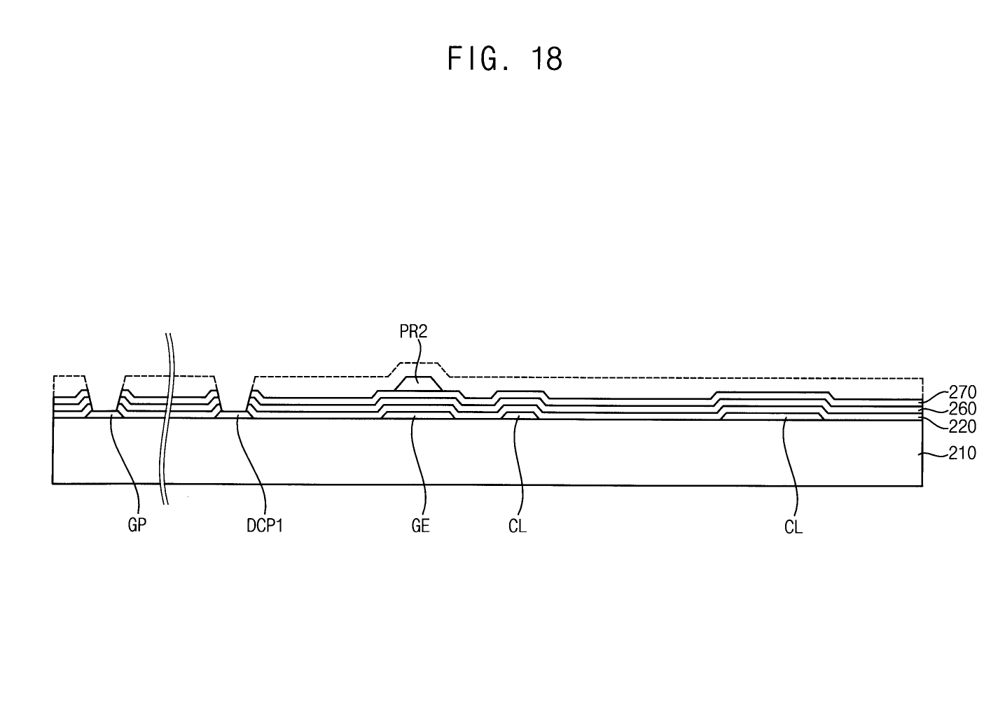

Referring to FIG. 18, the first photoresist pattern PR1 is partially removed through an ashing process. As a result, the smaller second thickness portion TH2 is removed, and the thicker first thickness portion TH1 partially remains to form a second photoresist pattern PR2 as illustrated. The second photoresist pattern PR2 overlaps with the gate electrode GE.

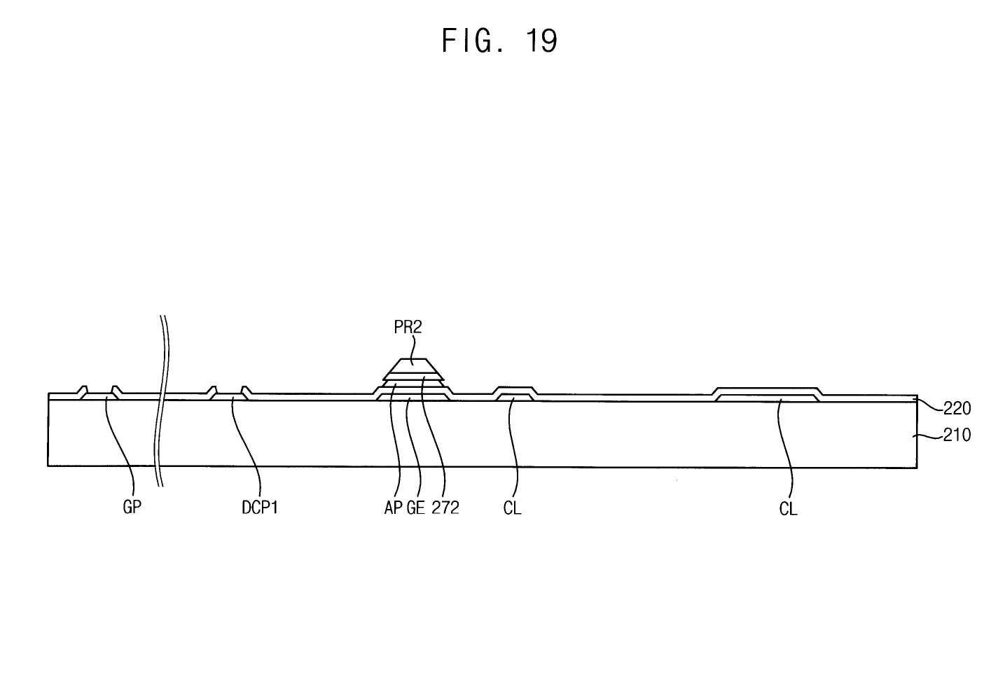

Referring to FIG. 19, the etch-stop layer 270 and the active layer 260 are etched by using the second photoresist pattern PR2 as a mask. For example, the etch-stop layer 270 may be dry-etched, and the active layer 260 may be wet-etched. As a result, a patterned active layer AP is formed, and a remaining etch-stop layer 272 is formed between the active pattern AP and the second photoresist pattern PR2.

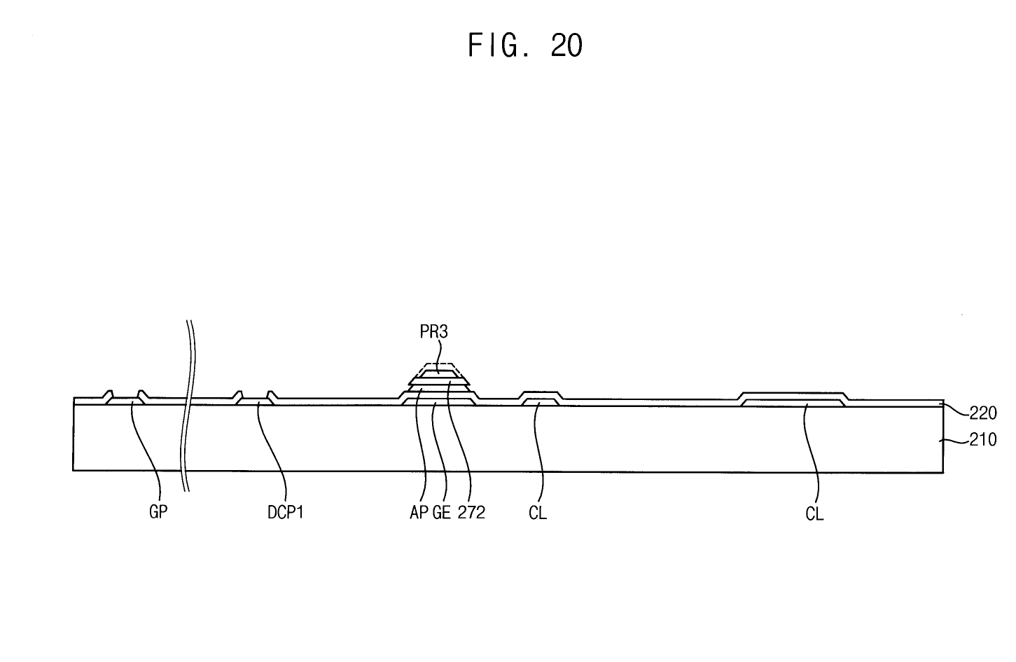

Referring to FIG. 20, the second photoresist pattern PR2 is partially removed, for example, through an asking process to form a third photoresist pattern PR3. The photoresist pattern PR3 has a smaller size than the second photoresist pattern PR2 so that an upper surface of the remaining etch-stop layer 272, near its sidewalls, is exposed.

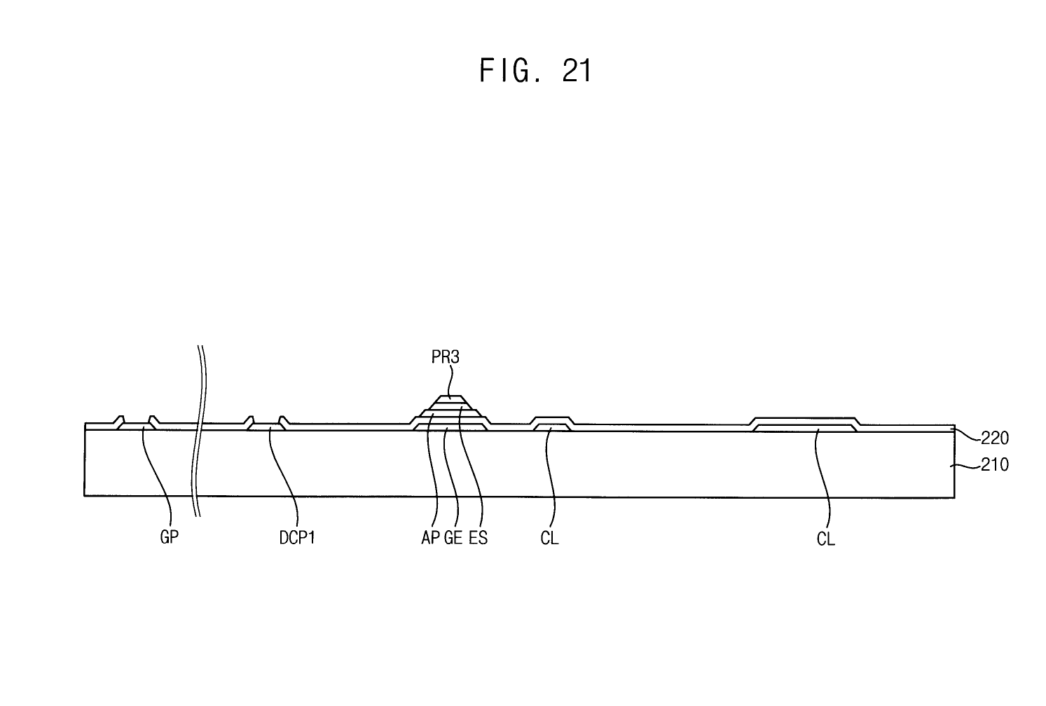

Referring to FIG. 21, the remaining etch-stop layer 272 is etched by using the third photoresist pattern PR3 as a mask to form an etch-stop pattern ES, for example one having a trapezoidal cross section as is illustrated. In the embodiment, the etch-stop pattern ES has a smaller size than the active pattern AP in a plan view.

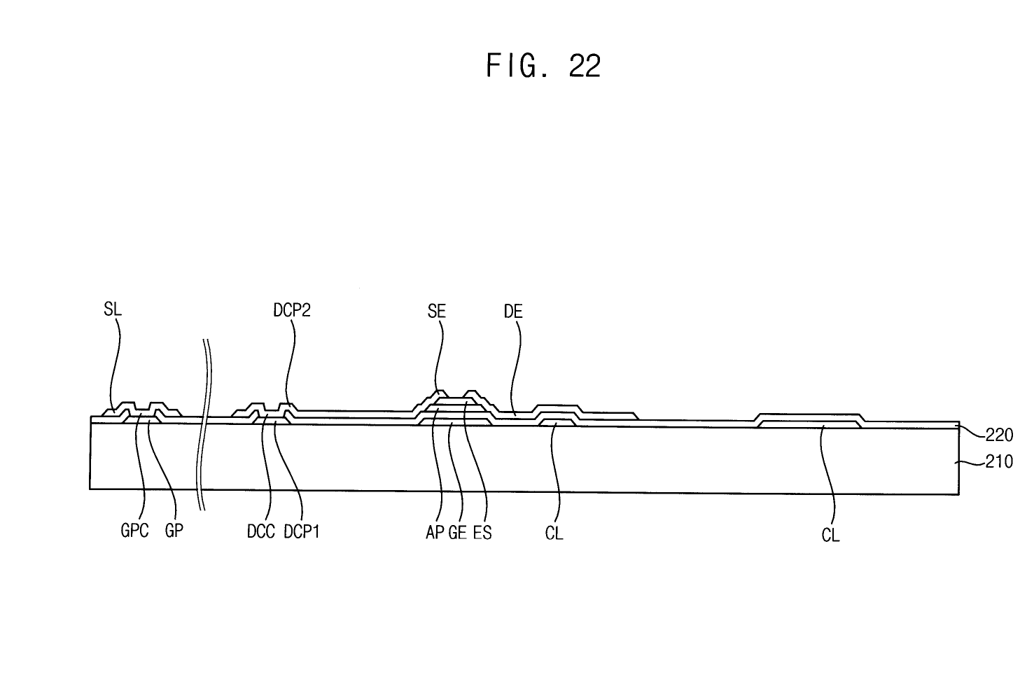

Referring to FIG. 22, a source metal layer is formed after the third photoresist pattern PR3 is removed. The source metal layer may have a substantially same composition as the gate metal layer. In another embodiment, the source metal layer has a single-layered structure of a transparent conductive oxide.

The source metal layer is patterned to form a source metal pattern including a second data connection pattern DCP2, a source electrode SE, a spaced apart drain electrode DE and a signal line SL. The second data connection pattern DCP2 is continuously connected to the source electrode SE.

The source electrode SE and the drain electrode DE contact respective sidewall surfaces of the active pattern AP. The second data connection pattern DCP2 includes a data contact DCC passing through the gate insulation layer 220 to contact the first data connection pattern DCP1. The signal line SL includes a gate pad contact GPC passing through a gate insulation layer 220 to contact a gate pad GP.

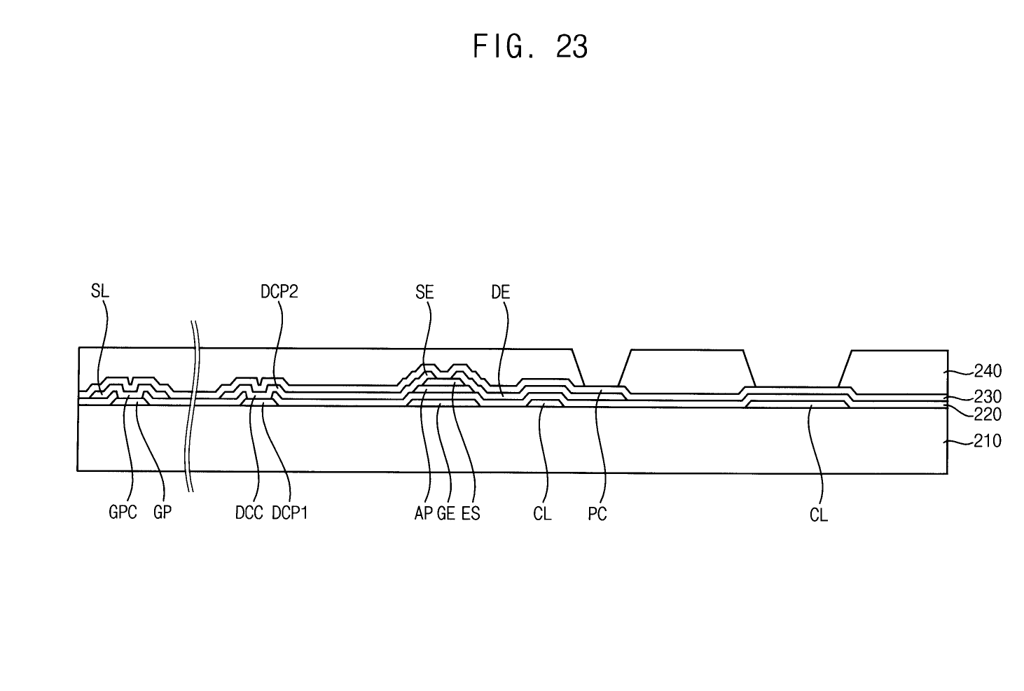

Referring to FIG. 23, a passivation layer 230 is formed to cover the source metal pattern, and an organic insulation layer 240 is formed on the passivation layer 230. The organic insulation layer 240 is patterned to form through holes. The through holes may overlap with the drain electrode DE and the common line CL.

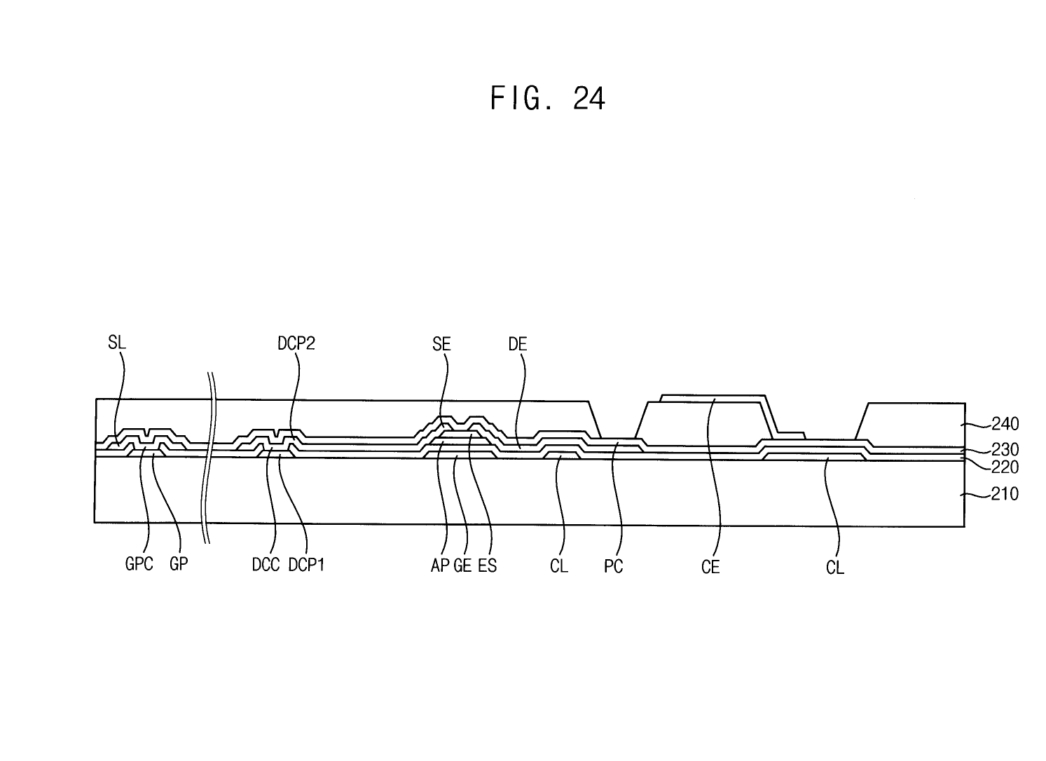

Referring to FIG. 24, a first transparent conductive layer is formed on the organic insulation layer 240, and then patterned to form a common electrode CE.

Referring to FIG. 25, a pixel insulation layer 250 is formed to cover the common electrode CE and the organic insulation layer 240. The pixel insulation layer 250, the passivation layer 230, and the gate insulation layer 220 are patterned to form through holes. For example, the through holes include a first through hole exposing the drain electrode DE, a second through hole exposing the common electrode CE and a third through hole exposing the common line CL.

Next, a second transparent conductive layer is formed on the pixel insulation layer 250, and patterned to form a pixel electrode PE and a connection member CM. The pixel electrode PE contacts the drain electrode DE and overlaps with the common electrode CE. The pixel electrode PE has an opening forming a slits portion SP extending in a direction. The connection member CM contacts the common electrode CE and the common line CL so that the common electrode CE and the common line CL are electrically connected to each other.

According to the embodiment, an etch-stop pattern and an active pattern may be formed by using a same mask. Furthermore, a gate pad may be directly connected to a gate lines driver circuit GD.

Exemplary embodiments may be used for manufacturing a display device such as a liquid crystal display, an organic electro luminescence display or the like, for example, a digital television, a monitor for a computer, a laptop computer, a mobile game player, a mobile music player, a mobile phone, a navigator or the like.

The foregoing is illustrative and is not to be construed as limiting thereof. Although a few exemplary embodiments have been described, those skilled in the art will readily appreciate in view of the foregoing that many modifications are possible in the exemplary embodiments without materially departing from the novel teachings, aspects, and advantages of the present disclosure. Accordingly, all such modifications are intended to be included within the scope of this disclosure. In the claims, means-plus-function clauses are intended to cover the structures described herein as performing the recited function and not only structural equivalents but also functionally equivalent structures.

What is claimed is:

1. A thin film transistor substrate comprising:
a base substrate;
a gate line disposed in a first layer on the base substrate and extending in a first direction;
a gate electrode electrically connected to the gate line;
a first data connection pattern comprised of first data connection pattern segments extending in a second direction different from the first direction and disposed in the same first layer as that of the gate line;
an active pattern overlapping with the gate electrode;
a source electrode electrically connected to the active pattern and disposed in a second layer above the first layer;
a drain electrode spaced apart from the source electrode; and
a second data connection pattern disposed in the same second layer as that of the source electrode and electrically connected to the source electrode and to the first data connection pattern.

2. The thin film transistor substrate of claim 1, further comprising:
a gate pad disposed in a same layer as that of the gate line and connected to the gate line; and
a signal line disposed in a same layer as that of the second data connection pattern and contacting the gate pad to provide a gate signal.

3. The thin film transistor substrate of claim 2, further comprising:
a gate insulation layer covering the gate line, the gate electrode and the first data connection pattern; and
an etch-stop layer covering the gate insulation layer and the active pattern.

4. The thin film transistor substrate of claim 3, wherein the second data connection pattern is disposed on the etch-stop layer, and contacts the first data connection pattern through the gate insulation layer and the etch-stop layer.

5. The thin film transistor substrate of claim 2, further comprising:
a gate insulation layer covering the gate line, the gate electrode and the first data connection pattern; and
an etch-stop pattern disposed on the active pattern.

6. The thin film transistor substrate of claim 5, wherein the second data connection pattern is disposed on the gate insulation layer, and contacts the first data connection pattern through the gate insulation layer.

7. The thin film transistor substrate of claim 1, wherein the second data connection pattern is connected to segments of the first data connection pattern, which segments are spaced apart from each other in the second direction.

8. The thin film transistor substrate of claim 1, wherein the second data connection pattern includes a transparent conductive oxide.

9. The thin film transistor substrate of claim 1, wherein the second data connection pattern has a single-layered structure or a multiple-layered structure including titanium.

10. The thin film transistor substrate of claim 1, wherein the active pattern includes a semiconductive oxide.

11. A method for manufacturing a thin film transistor substrate, the method comprising:
forming a gate metal pattern in a first layer on a base substrate, the gate metal pattern including a plurality of gate lines extending in a first direction, gate electrodes electrically connected to respective one of the gate lines and a first data connection pattern having spaced apart segments extending in a second direction different from the first direction, the segments being spaced apart from the gate lines;
forming active patterns each overlapping a respective one of the gate electrodes; and
forming a source metal pattern in a second layer disposed above the first layer, the source metal pattern including a plurality of source electrodes respectively electrically connected to corresponding ones of the active patterns, a plurality of drain electrodes respectively spaced apart from corresponding ones of the source electrodes, and a second data connection pattern having parts respectively electrically connected to corresponding ones of the source electrodes and to corresponding segments of the first data connection pattern.

12. The method of claim 11, wherein the gate metal pattern further includes a gate pad connected to the gate line, and the source metal pattern further includes a signal line contacting the gate pad to provide a gate signal.

13. The method of claim 12, further comprising:
forming a gate insulation layer covering the gate lines, the gate electrodes and the segments of the first data connection pattern; and
forming an etch-stop layer covering the gate insulation layer and the active patterns.

14. The method of claim 13, further comprising:
forming a first photoresist pattern on the etch-stop layer, the first photoresist pattern having through holes overlapping with the gate pads and with segments of the first data connection pattern, the first photoresist pattern including a first thickness portion and a second thickness portion thicker than the first thickness portion;
etching the etch-stop layer and the gate insulation layer by using the first photoresist pattern as a mask to expose the gate pads and parts of the segments of the first data connection pattern;
partially removing the first photoresist pattern to form a second photoresist pattern having through holes overlapping with the active patterns; and
etching the etch-stop layer by using the second photoresist pattern as a mask to expose contactable portions of the active pattern.

15. The method of claim 12, further comprising:
forming a gate insulation layer covering the gate lines, the gate electrodes and the first data connection pattern.

16. The method of claim 15, wherein forming the active pattern comprises:
forming an active layer on the gate insulation layer;
forming an etch-stop layer on the active layer;
forming a first photoresist pattern on the etch-stop layer, the first photoresist pattern having through holes overlapping with the gate pad and the first data connection pattern, the first photoresist pattern including a first thickness portion and a second thickness portion thinner than the first thickness portion;
etching the etch-stop layer, the active layer and the gate insulation layer by using the first photoresist pattern as a mask to expose the gate pad and the first data connection pattern;
partially removing the first photoresist pattern to form a second photoresist pattern overlapping with the active pattern;
etching the etch-stop layer and the active layer by using the second photoresist pattern as a mask to form an active pattern;
partially removing the second photoresist pattern to form a third photoresist pattern; and
etching the remaining etch-stop layer by using the third photoresist pattern as a mask to form an etch-stop pattern.

17. The method of claim 11, wherein respective parts of the second data connection pattern are connected to corresponding segments of the first data connection pattern.

18. The method of claim 11, wherein the source metal pattern includes a transparent conductive oxide.

19. The method of claim 11, wherein the source metal pattern has a single-layered structure or a multiple-layered structure including titanium.

20. The method of claim 11, wherein the active pattern includes a semiconductive oxide.
